(19) United States
(12) Patent Application Publication
(10) Pub. No.: US 2011/0000529 A1
(43) Pub. Date: Jan. 6, 2011

(54) Cathode Electrode for Plasma CVD and Plasma CVD Apparatus

(75) Inventor: Masayasu Suzuki, Kyoto-shi (JP)

Correspondence Address: DLA PIPER US LLP, 1999 AVENUE OF THE STARS, SUITE 400, LOS ANGELES, CA, 90067-6023, US

(73) Assignee: SHIMADZU CORPORATION, Kyoto-shi, Kyoto (JP)

(21) Appl. No.: 12/920,303

(22) PCT Filed: Apr. 8, 2008
(86) PCT No.: PCT/JP2008/056957

§ 371 Date: Aug. 30, 2010

(51) Int. Cl. H01L 31/0256; H01J 61/28; H01L 31/18

(52) U.S. Cl. 136/252; 313/231.31; 118/723 I; 257/E31.003; 257/E31.001

(57) ABSTRACT

An arrangement of a cathode electrode for plasma CVD forms a radio frequency capacity coupled plasma by applying radio frequency radiation, in which the cathode electrode is disposed so as to face an anode electrode. The facing surface which faces the anode electrode is formed to have a concavo-convex shape comprising concaves constituted by a bottom surface and convexes constituted by a plurality of protrusions protruding toward the anode electrode from the bottom surface constituting the concaves. At least one of the protrusions forming the convexes has at least one reactive gas ejection nozzle on a side surface, which is capable of ejecting a reactive gas. An ejection direction of the reactive gas from the reactive gas ejection nozzle is substantially parallel to the bottom surface constituting the concaves. The optimization of the cathode electrode allows generation of dense plasma.

### TECHNICAL FIELD

The present invention relates to a radio frequency capacity-coupled plasma CVD, a cathode electrode for plasma CVD that uses hollow cathode discharge, and a plasma CVD apparatus that is equipped with the cathode electrode for plasma CVD use.

### BACKGROUND ART

A deposition apparatus is known which deposits films on a substrate to manufacture thin films and the like. One example of such deposition apparatus is a plasma CVD apparatus which is used to manufacture semiconductor devices such as TFT arrays and to manufacture thin films and the like used in solar cells, photosensitive drums, liquid crystal displays and the like.

A plasma CVD apparatus that uses capacity-coupled parallel plate electrodes have been known for some time. With a plasma CVD apparatus that uses capacity-coupled parallel plate electrodes, parallel plate electrodes serving as a cathode and an anode are installed in a reaction chamber. A low frequency or radio frequency power supply supplies power to the electrodes while a reactive gas is then introduced to the reaction vessel to generate plasma which is used for the deposition of films.

What is desirable in semiconductor manufacturing is to increase the area of the thin films. For example, with liquid crystal panels used in liquid crystal displays, a larger panel size is desirable since this allows larger images to be displayed. Even in solar cells, a larger size is desirable since this improves power generation performance and productivity.

A capacity-coupled plasma CVD apparatus that uses hollow cathode discharge for increased film deposition efficiency has been proposed (e.g., Patent Literature 1 and 2).

FIG. 18 shows one example of the construction of a previous capacity-coupled plasma CVD apparatus that uses hollow cathode discharge.

With the plasma CVD apparatus 110 shown in FIG. 18, cathode electrode 101 and anode electrode 102 are disposed in vacuum chamber 111 to oppose each other. Power supply 115a supplies a low frequency or radio frequency AC power with electrode 101. The substrate 100 to be process is placed on the anode electrode 102 which can be heated by an internalized heater 117.

Vacuum pump 113 evacuates vacuum chamber 111, and a reactive gas is introduced into the vacuum chamber through reactive gas introduction tube 112.

The cathode electrode 101 integrates a shower-head type opening to introduce the reactive gas to the surface of the substrate. The surface of the cathode plate has concave and convex sections where long, cylindrical convex sections arranged in a grid-like pattern are connected by grooves. Small holes are formed in the long, cylindrical convex sections to serve as openings for the introduction of the reactive gas. The reactive gas that is introduced from the reactive gas introduction tube 112 passes through the holes in the convex section and are introduced to the substrate side.

Patent Literature 1: JP 2002-237459A (paragraph 0015)

Patent Literature 2: JP 2004-296526A (paragraph 0008)

### DISCLOSURE OF THE INVENTION

### Problems to be Solved by the Invention

With a previous cathode electrode for use in hollow cathode discharge, holes are created by a machining process such as cutting of a plate material that constitutes a flat cathode electrode to form concave-convex sections that become hollow cathode electrodes. Very small holes having a diameter of, for example, approximately 0.4 mm, for discharging the reactive gas must be formed in large numbers along the bottom surface of the convex sections of the cathode electrode. Furthermore, the discharging direction of the reactive gas discharge holes have to be drilled perpendicular to the surface of the substrate.

As afore-described, previous cathode electrodes are constructed so that reactive gases are discharged from numerous very small holes that are formed along the bottom surface of the convex sections of the cathode plate in a direction perpendicular to the substrate. This makes the amount of reactive gas that is discharged from the numerous reactive gas discharge holes to be non-uniform and creates problems of the film thickness and the film quality of the thin film that is deposited on the surface of the same substrate to be non-uniform.

Furthermore, because the uniformity of the film thickness of a deposited thin film is intimately related to the reactive gas discharge holes, this creates the problem that, for any given conditions that are set for the reactive gas discharge holes such as the locations where the reactive gas discharge holes are formed in the cathode plate and the number of reactive gas discharge holes that are provided, the optimum range for process conditions such as gas flow rate, gas flow rate ratios of different gases, pressure, applied electrical power, substrate temperature and the like becomes narrow. For example, with respect to the substrate processing conditions, it is difficult to select an optimum pressure within the optimum pressure range that is determined by the conditions that are set for the reactive gas discharge holes.

Furthermore, because machining such as cutting and drilling forms the concave-convex sections that become hollow cathode electrodes, the fabrication of the cathode electrode is difficult, and the fabrication cost becomes high.

Furthermore, because numerous small holes are formed along the bottom surface of the cathode plate, another problem is the difficulty of maintenance of the cathode electrodes.

The holes in the convex sections disclosed in Patent Reference 1 are connected by grooves. With this construction, the insides of the holes become hollow cathode discharge electrode space where a high density plasma is generated. However, high density plasma is not generated in the grooves that connect the holes since the supply of the reactive gas is insufficient there even though the electron density may be sufficiently high. This can cause problems with the uniformity of the deposited film.

Furthermore, another problem is that, because of the limited effective area available for hollow cathode discharge, the film deposition rate cannot be sufficiently improved.

It is the object of the present invention to solve the afore-described problems of previous cathode electrodes and to generate high density plasma by the optimization of the cathode electrodes.

More specifically, it is the object of the present invention to optimize the cathode electrodes and thus increase the optimum range of plasma conditions, and to also increase the effective area of the electrodes that contribute to discharge and thus increase the film deposition rate.

Furthermore, another object of the present invention is to optimize the cathode electrode, thereby creating a cathode structure that can be easily and inexpensively manufactured and maintained.

### Means for Solving the Problems

In a cathode electrode for use with plasma CVD wherein a radio frequency capacity-coupled plasma is formed by the application of radio frequency, with the present invention, the cathode electrode is disposed to oppose the anode electrode, and the surface of the cathode electrode opposing the anode electrode is constructed to have concave-convex sections, the convex section having the bottom surface, and the concave section having a plurality of projections that protrude from the bottom surface of said convex section towards the anode electrode.

Formed on the side wall of at least one of the projections of the concave section is at least one reactive gas discharge hole through which a reactive gas is discharged. The discharge direction of the reactive gas from said reactive gas discharge hole is substantially parallel to the bottom surface of the convex sections.

A hollow cathode is formed by forming the cathode electrode with concave-convex sections. Electrons which are emitted by the incidence of ions onto the cathode surface are confined between the cathode electrodes having a concave section and a convex section, thus forming a high-density electron space. By discharging the reactive gas into said high-density electron space, a high-density plasma is generated. By making the discharge direction of the reactive gas to be parallel to the bottom surface of the convex sections of the cathode electrode, the reactive gas can be uniformly introduced into the high-density electron space.

This increases the probability of collision between the high-energy electrons and the reactive gas and forms a uniform high-density plasma between the projections on the concave section.

The projections which constitute the concave section of the cathode electrode have formed within it a reactive gas flow path for supplying the reactive gas to the reactive gas discharge hole. The reactive gas flow path includes a first flow path that is formed along the axial direction of the projection and a second flow path which branches from said first flow path and connects to the reactive gas discharge hole, the second flow path extending in a direction approximately parallel to the bottom surface.

After a reactive gas is introduced by the first flow path in the axial direction of the projection, the reactive gas branches into the second flow path and is discharged from the reactive gas discharge hole into the space formed by the concave-convex section. The discharge direction from the reactive gas discharge hole is approximately parallel to the bottom surface of the concave sections and the substrate surface. By setting the discharge direction of the reactive gas to be approximately parallel to the bottom surface of the concave sections and the substrate surface, the reactive gas can be uniformly distributed in the high-density electron space that is formed on the cathode electrodes.

The distance separating adjacent projections of the cathode electrode can be defined based on the electron mean free path. For example, setting the distance to be about 1- to 1.5-fold of the electron mean electron free path ensures that there is no space where the plasma can be in a hollow state. This increases the area efficiency for the generation of high density plasma. An example of the range of distance between cathode electrodes is 0.5 mm to 7 mm.

The diameter of the reactive gas discharge hole in the projections of the cathode electrode can range between 0.1 mm to 1.0 mm. The height of the projections of the cathode electrode from the bottom surface can range between 3 mm and 15 mm.

Fine concave-convex sections are formed on the bottom surface of the cathode electrodes and the side surface of the projections by ceramic brass treatment or by treatment with a chemical solution to provide a matte finish to the surface. This increases the electrode area of the cathode electrode and increases electron emission efficiency.

If aluminum electrodes are used, the effective area for electron emission can be increased by providing a surface treatment having an alumite treatment and a sealing treatment. This also improves durability against etching gases.

The distance between the cathodes is a major factor that determines the properties of a hollow cathode discharge. With the present invention, a wide variety of inter-electrode distances are used in the layout of the cathode electrodes, and a close-packed array is used to provide a wide latitude in the optimum settings for process parameters such as pressure, temperature and gas species. The close-packed array of the present invention allows electrodes to be laid out using a plurality of distances between the electrodes, thus allowing the use of a wide variety of process conditions.

In this close-packed array, the cathode electrodes are laid out so that the distance between adjacent projections is, as afore-described, approximately 1- to 1.5-fold of the electron mean free path.

Examples of a close-packed array that can be used are a square close-packed array and a hexagonal close-packed array. With a square close-packed array, the projection of the cathode electrode is positioned on the bottom surface of the concave at the four vertices of a square and at the center surrounded by the four vertices. With a hexagonal close-packed array, the projection of the cathode electrode is positioned on the bottom surface of the concave at the six vertices of a regular hexagon and at the center surrounded by the six vertices.

The projections of the cathode electrodes may or may not include a reactive gas discharge hole formed therein. These projections are positioned on the bottom surface of the concave with a predetermined distribution.

The projections may be arranged so that projections with a reactive gas discharge hole formed therein and those without a reactive gas discharge hole occur in a ratio of 1:4 and can be provided as a hexagonal close-packed array.

The projections of the cathode electrodes can have any shape. They may be a cylindrical shape with a circular horizontal cross-section, or they may be formed as a polygonal column with a polygonal horizontal cross-section.

Furthermore, each of the projections of the cathode electrode can be constructed to have at least one reactive gas discharge hole so that all of the projections have a reactive gas discharge hole.

The cathode electrode has an outer peripheral wall that surrounds the projections located within it. The height of the wall face of said outer peripheral wall can be made to be approximately equal to the height of the projection. The cathode discharge space can be the space formed between the projections or the space formed between the projection and the outer wall.

Furthermore, with the cathode electrode according to the present invention, the projections can be formed as columns which are inserted into openings that are formed in the cathode base plate. Said column and cathode base plate configuration eliminates the time required for the fine fabrication of the cathode plate and reduces the fabrication time.

Additionally, the plasma CVD apparatus according to the present invention is a plasma CVD apparatus wherein a radio frequency capacity-coupled type plasma is formed by the application of a radio frequency and may include: a vacuum chamber equipped with a cathode electrode and an anode electrode; a reactive gas supply unit that supplies a reactive gas to the upstream side of the cathode electrode in the vacuum chamber; an exhaust unit that expels the reactive gas in the vacuum chamber to outside the process chamber; a controller that controls the pressure inside the vacuum chamber to a predetermined pressure; an electrical power supply unit that supplies electrical power across the cathode electrode and the anode electrode; and a substrate holder that locates a substrate to be processed between the cathode electrode and the anode electrode.

The plasma CVD apparatus uses the cathode electrodes according to the present invention so that the reactive gas that is supplied by the reactive gas supply unit at an upstream side of the cathode electrode is discharged from the reactive gas discharge hole provided in the cathode electrode into the space between the cathode electrode and the anode electrode.

Furthermore, the plasma CVD apparatus according to the present invention can be used to manufacture solar cells that include a silicon semiconductor thin film, silicon nitride thin film, silicon oxide thin film, silicon oxynitride thin film or carbon thin film.

### Effect of the Invention

According to the present invention, the cathode electrode is optimized to generate a high density plasma. Furthermore, according to the present invention, by optimizing the cathode electrode, the optimum range of plasma conditions is broadened which increases the effective area of the electrodes contributing to the discharge and improves the film deposition rate.

Furthermore, by optimizing the cathode electrode, the cathode electrode is configured so that it can be easily and inexpensively fabricated, thus facilitating the maintenance work performed on the cathode.

### BRIEF DESCRIPTION OF THE FIGURES

FIG. 1 is a schematic diagram showing the positional relationship between an anode electrode and a cathode electrode of a hollow cathode electrode and how power is supplied.

FIG. 2 shows an example of an arrangement of a plurality of hollow cathode electrodes.

FIG. 3 shows an example of an arrangement of a plurality of hollow cathode electrodes.

FIG. 4 shows a graph of the relationship between nitrogen (N) gas pressure (Pa) and mean free path (MFP) for ambient temperatures of 373K, 673K and 773K.

FIG. 5 shows a graph of the relationship between nitrogen gas pressure and cathode electrode distance for nitrogen gas at an ambient temperature of 673K.

FIG. 6 shows a graph of the relationship between mean free path (MFP) and gas pressure for SiH₄, NH₃ and N₂ gases at an ambient temperature of 673K.

FIG. 7 shows a schematic view of a Plasma CVD apparatus according to the present invention.

FIG. 8 shows a schematic view of the cathode electrode section of a Plasma CVD apparatus according to the present invention.

FIG. 9 shows a plan view and a cross-sectional view of the cathode electrodes according to the present invention.

FIG. 10 is a perspective view of the cathode electrodes according to the present invention.

FIG. 11 shows how the cathode electrodes according to the present invention are surrounded by an outer wall.

FIG. 12 shows a hexagonal close-packed array and a square close-packed array.

FIG. 13 shows an example of a configuration where a reactive gas discharge hole is formed in each projection (cathode column).

FIG. 14 shows an example of a configuration for forming a reactive gas discharge hole in each projection (cathode column).

FIG. 15 shows an example of a configuration for forming a reactive gas discharge hole in each projection (cathode column).

FIG. 16 shows an example of a configuration wherein projections with a reactive gas discharge hole and projections without a reactive gas discharge hole co-exist in a predetermined distribution.

FIG. 17 shows different examples of shapes of the cathode electrode projection (cathode column) according to the present invention.

FIG. 18 shows an example of the configuration of a previous capacity-coupled plasma CVD apparatus that uses hollow cathode discharge.

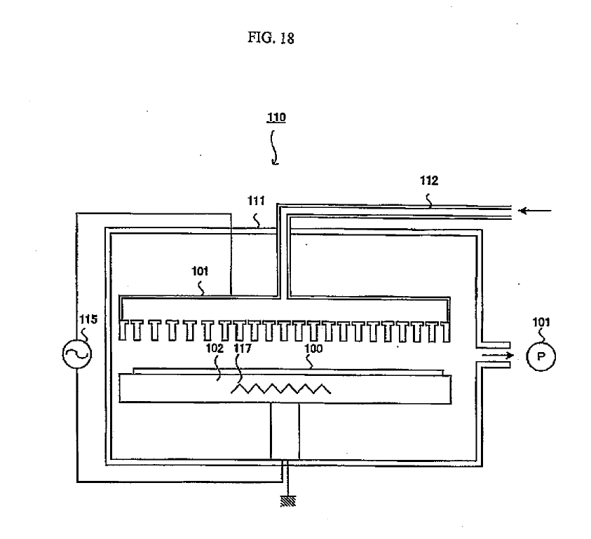

### DESCRIPTION OF THE NUMERICAL REFERENCES

1. Cathode electrode
1A. Concave section
1B. Convex section
1a. Projection
1b. Insertion area
1c. Cathode column
1d. Hole
1e. Gas flow path
1f. Opening
1g. Bottom surface
1h. Cathode base plate
1i. Outer wall
1j. Wall face
1k. Opening
2. Anode electrode
10. Plasma CVD apparatus
11. Vacuum chamber
12. Gas supply unit
13. Exhaust unit
14. Pressure control unit
14a. Valve controller
14b. Exhaust rate control valve
15. Electrical power supply unit
15a. Power supply
15b. Matching device
16. Substrate holder
17. Heater
20. Reactive gas
21. Cathode fall
22. Negative glow
23. Positive column
24. Hollow portion
100. Substrate
101. Cathode electrode
102. Anode electrode
110. Apparatus
111. Vacuum chamber
112. Reactive gas introduction tube
113. Vacuum pump
115a. Power supply
117. Heater
MFP: Mean free path
ne: Electron density
S1: Shortest distance
S2: Longest distance
T: Plate thickness
Te: Electron temperature
λd: Debye length
λe: Mean free path
λg: Mean free path

### BEST MODE FOR PRACTICING THE INVENTION

An embodiment of the present invention is described next in detail with reference to drawings.

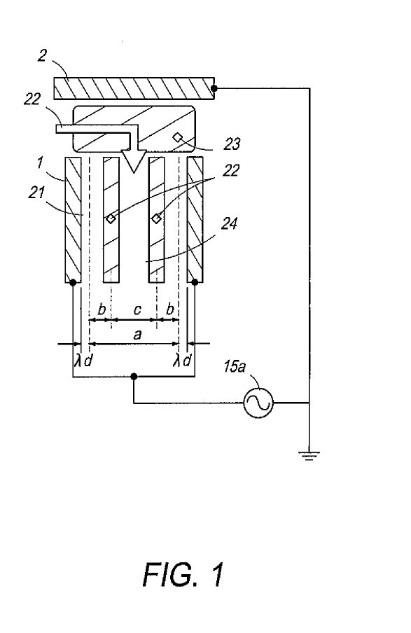

The configuration of the hollow cathode electrodes and their operation are described first with reference to FIG. 1 through FIG. 7. FIG. 1 is a schematic view showing the positional relationship between the anode electrode and the cathode electrode of a hollow cathode electrode and how power is supplied.

With the hollow cathode electrode, power supply 15a is connected across the cathode electrode 1 and the anode electrode 2, and a low frequency or a radio frequency alternating current is applied. Irradiation with ions causes electrons to be emitted from the electrode surface of cathode electrode 1. The hollow cathode electrode confines the emitted electrons in the region between cathode electrodes 1, thereby forming a high density electron space. A high density plasma is generated by supplying a reactive gas 20 into the high density electron space.

Formed between cathode electrode 1 and anode electrode 2 are, from the cathode electrode 1 side, cathode fall 21 where the electrical field strength decreases linearly, negative glow 22 where the electrical field strength becomes zero, and positive column 23 that emits light uniformly where the ion density and electron density are equal and no overall charge appears externally. The positive column 23 is in a plasma state. With the hollow cathode electrode, the cathode electrodes 1 are made to oppose each other so that cathode fall 21 and negative glow 22 are formed at each of both cathode electrodes 1.

The electron confinement occurs when the cathode fall 21 that is created on the side surface of cathode electrode 1 causes the electrons to be Debye blocked, thereby not impinging on the surface of cathode electrode 1, resulting in a pendulum effect occurring at the side surface of cathode electrode 1 involving the repulsion and recoil of electrons and the formation of a high-density electron space.

Almost all of the electrons that collide with the gas molecules of the reactive gas are elastically scattered and thus retain their high energy. Because these electrons are scattered while recoiling between the side surfaces of the cathode electrodes, a macroscopic observation shows the electrons as forming a uniform high electron density space within the same plane.

The plasma that is generated is maintained by the collision between the reactive gas and the confined high-energy electrons. This means that the location where the high density plasma is generated is determined by the positional relationship between the space where the electrons are confined and the position where the reactive gas is discharged.

In FIG. 1, the dimension “λd” within cathode fall 21 is the Debye length. Electrons cannot penetrate more inwardly (toward the cathode electrode) than the Debye length λd and are instead repulsed. Also, in FIG. 1, dimension “b” identifies the electron mean free path, and dimension “c” identifies the distance between adjacent negative glows 22.

The distance between adjacent cathode electrodes 1 is a+λd. If the Debye length λd is sufficiently smaller than dimension a, this distance can be represented as a. The dimension a is the sum of twice the electron mean free path and c (i.e., (2b+c)).

The electrons that are emitted from cathode electrode 1 collide with the reactive gas near the electron mean free path b, ionize the gas molecules and generate plasma. Because the plasma is generated as if it were attached to the electrode surface of cathode electrode 1, if the distance between the negative glows 22 is large, a hollow portion 24 is created in this area where no plasma is present.

Here, the relationship between Debye length λd, electron temperature Te and electron density ne is expressed by equation (1) below.

Equation 1

λd=7.4*10³*√(Te/ne) (1)

Table 1 shows an example of the values of electron temperature Te and electron density ne of a typical high density glow discharge plasma that were calculated using equation (1) above.

TABLE 1

| Electron temperature | Electron density | Debye length | |
|---|---|---|---|
| Te | Ne | λd | |
| eV | m-3 | m | mm |
| 10 | 1.0E+17 | 7.40E−005 | 0.07 |
| 5 | 1.0E+17 | 5.23E−005 | 0.05 |
| 2 | 1.0E+17 | 3.31E−005 | 0.03 |
| 10 | 1.0E+18 | 2.34E−005 | 0.02 |
| 5 | 1.0E+18 | 1.65E−005 | 0.02 |
| 2 | 1.0E+18 | 1.05E−005 | 0.01 |

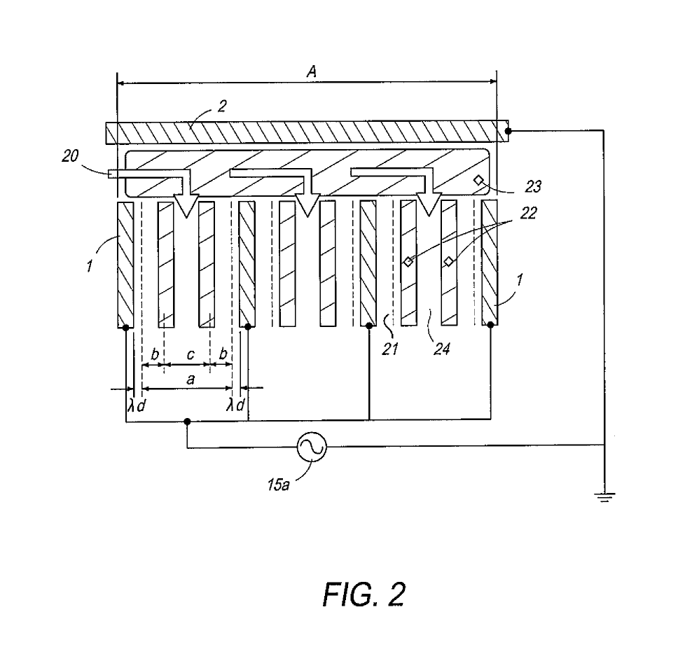

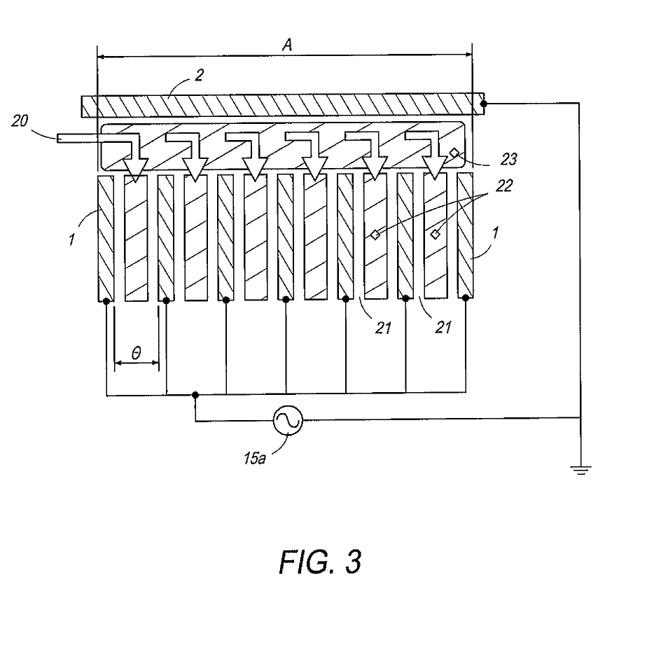

FIG. 2 and FIG. 3 show an example where a plurality of the hollow cathode electrodes shown in FIG. 1 is arranged. Arranging a plurality of hollow cathode electrodes on the plane allows their use for the deposition of a film over a large area.

FIG. 2 shows the case where there are many hollow portions c of the plasma. FIG. 3 shows the case where there are very few hollow portions c of the plasma. Assuming that the distance e between adjacent cathode electrodes 1 is approximately 1- to 1.5-fold of the electron mean free path, the space between adjacent cathode electrodes 1 is filled with plasma. By repeating this configuration using a plurality of cathode electrodes on the plane, a high density plasma with good area efficiency is formed.

The electron mean free path is determined by ambient temperature, pressure and the size of the gas molecules. The optimum layout for generating a hollow cathode discharge with the highest area efficiency requires setting the distance between the electrode surfaces of the cathode electrodes that serve as hollow cathode electrode to be approximately 1- to 1.5-fold of the electron mean free path and to position the projections that constitute the concave sections of the cathode electrodes using this distance.

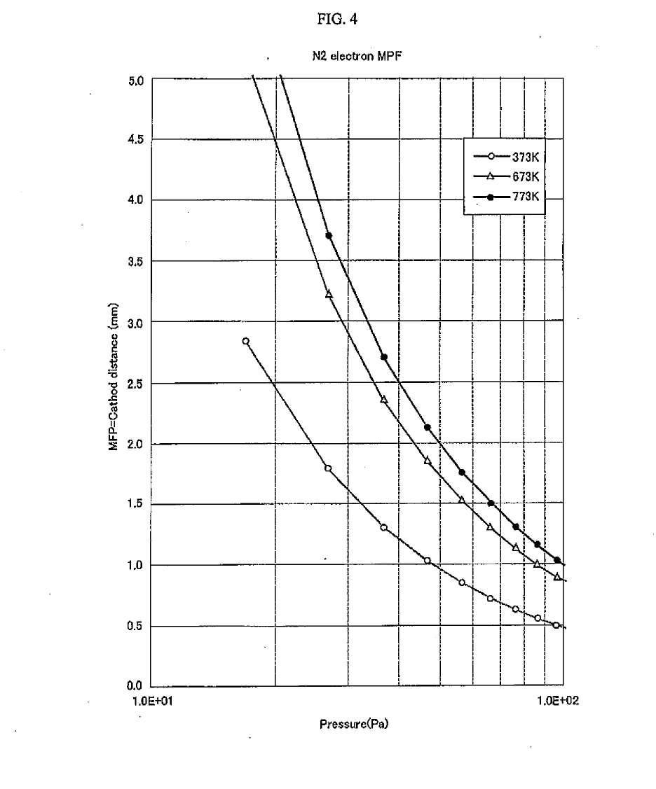

FIG. 4 shows the relationship between nitrogen (N) gas pressure (Pa) and mean free path (MFP) for ambient temperatures of 373K, 673K and 773K.

The mean free path λg of the gas particles is represented by equation (2) below.

λg=3.11×10−24×T4/(P×d2) (2)

The electron mean free path λe is represented by equation (3) below.

λe=λg×4\sqrt{2} (3)

Here, T (K) represents the ambient temperature, P (Pa) the pressure and d(m) the diameter of the gas molecule. For a nitrogen gas at 400° C. and 67 Pa (0.5 Torr), the electron mean free path λe is 1.22 mm.

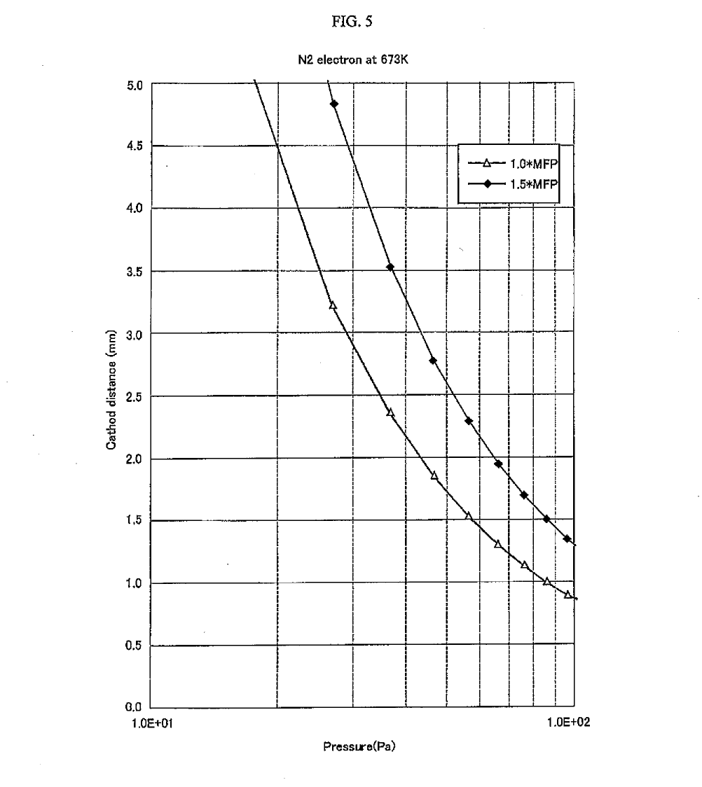

FIG. 5 shows the relationship between nitrogen gas pressure whose ambient temperature is 673K and the distance between cathode electrodes. Here, the inter-cathode electrode distance is assumed to be 1-fold and 1.5-fold of the electron mean free path λe. In FIG. 5, the curve connecting the open triangles plots the relationship when the inter-cathode electrode distance is set to 1.0-fold of the mean free path λe. The curve connecting the filled triangles plots the relationship when the inter-cathode electrode distance is set to 1.5-fold of the mean free path λe. The electron mean free path λe can be determined from the afore-described FIG. 4.

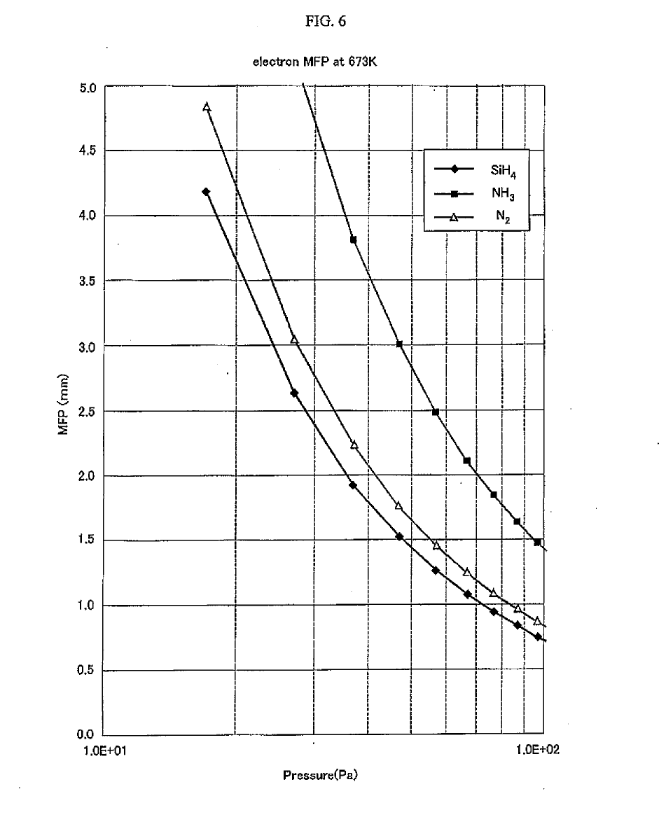

FIG. 6 shows the relationship between gas pressure (Pa) and mean free path (MFP) for SiH, NH and N gases at an ambient temperature of 673K.

With a plurality of hollow cathode electrodes arranged as shown in afore-described FIG. 3, setting the inter-cathode electrode distance to approximately 1- to 1.5-fold of the electron mean free path λe provides a configuration that minimizes the hollow portion c of the plasma and generates a high density plasma by efficiently supplying the reactive gas to the high-density electron space.

For the afore-described cathode electrode, the present invention provides a configuration wherein the inter-cathode electrode distance is set to be approximately 1- to 1.5-fold of the electron mean free path λe so as to form a high-density electron space into which the reactive gas is efficiently supplied.

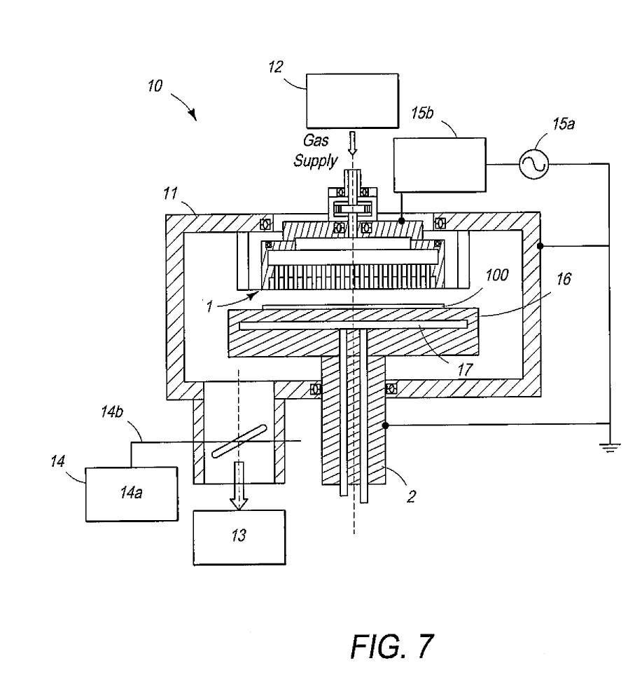

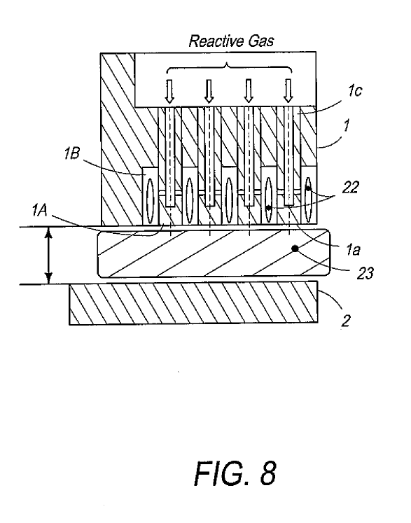

FIG. 7 and FIG. 8 show schematic views of the plasma CVD apparatus according to the present invention. FIG. 8 shows the cathode electrode portion.

With the plasma CVD apparatus 10, the cathode electrode 1 and the anode electrode 2a are arranged to oppose each other inside the vacuum chamber 11. An alternating current power supply of either a low frequency or a radio frequency is supplied across the two electrodes from power supply 15a. Heater 17 is installed inside anode electrode 2 to allow heating. Substrate 100 to be processed is placed on substrate holder 16. Matching device 15b for matching the impedance is connected between power supply 15a and cathode electrode 1 to reduce the loss in electrical power supply to cathode electrode 1 caused by reflected electrical power.

Gases in the vacuum chamber 11 is exhausted by an exhaust unit 13 such as a vacuum pump. Reactive gases are introduced into the vacuum chamber 11 by gas supply unit 12. The pressure inside the vacuum chamber 11 is controlled by pressure controller 14. The pressure control unit 14 may be constructed, for example, using an exhaust rate control valve 14b that controls the exhaust rate of exhaust unit 13 and a valve controller 14a.

The cathode electrode 1 is constructed by installing a plurality of projections 1a on the bottom surface 1g of the cathode base plate 1h so that the projections protrude toward anode electrode 2. The concave section 1A formed by the plurality of projections 1a and the convex section 1B formed by the bottom surface 1g of the cathode base plate 1h form concave-convex sections. Gas flow path 1e through which the reactive gas flows is formed within projection 1a so that a reactive gas is discharged into the space between the projections 1a from the reactive gas discharge hole 1d that is formed in the side wall portion. The reactive gas that is discharged from the reactive gas discharge hole 1d is directed to be approximately parallel to the bottom surface 1g of the cathode base plate 1h so that the space bounded by the plurality of projections 1a is fully filled with the reactive gas.

The reactive gas is introduced into the gas flow path 1e from opening 1f that is formed on the surface that opposes the bottom surface 1g of the cathode base plate 1h.

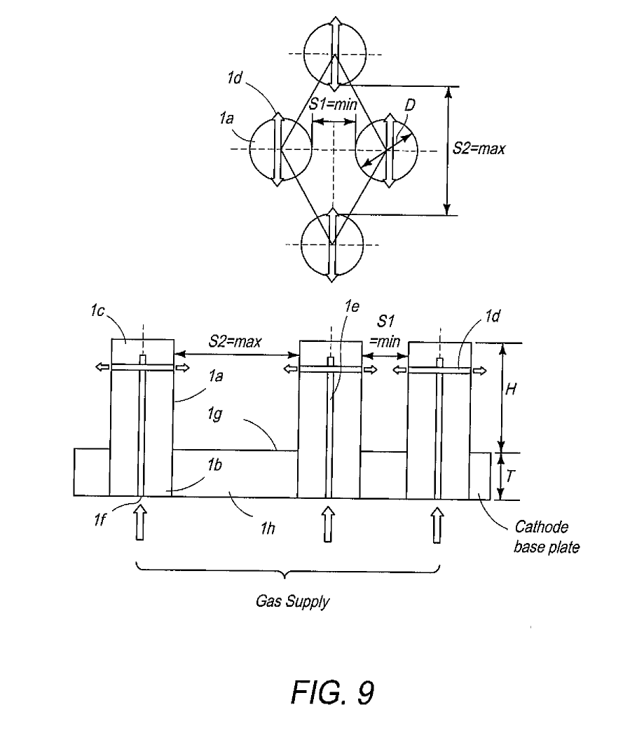

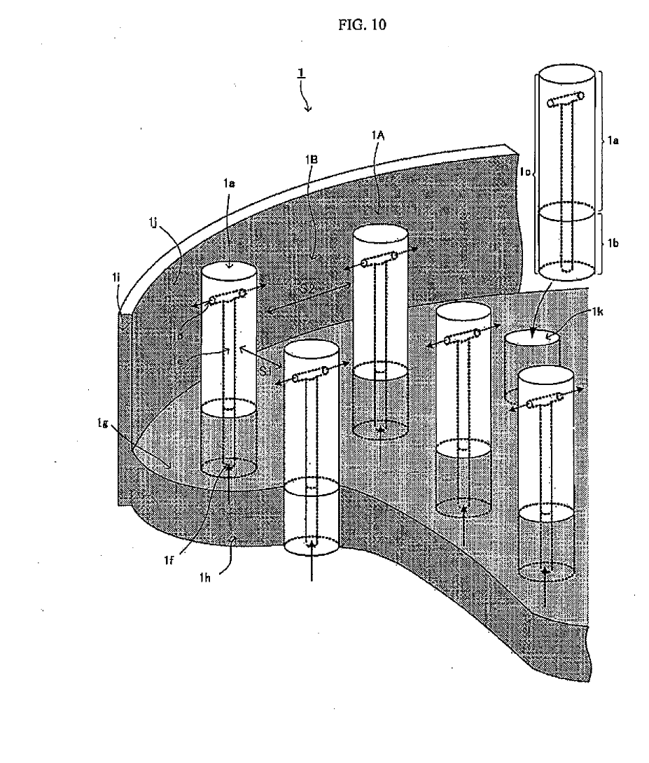

FIG. 9 and FIG. 10 show the configuration of the cathode electrode. FIG. 9 shows a plan view and a sectional view of the cathode electrode. FIG. 10 shows a perspective view of the cathode electrode.

The cathode electrode according to the present invention includes a plurality of projections 1a forming the concave section and a cathode base plate 1h that holds these projections 1a. Each projection 1a includes an insertion portion 1b which is inserted into the cathode base plate 1h and a cathode column 1c. The cathode column 1c is constructed so that it is attached by inserting insertion portion 1b into opening 1k that is opened in the cathode base plate 1h.

A gas flow path 1e is formed in the cathode column 1c so that the reactive gas flows through projection 1a and insertion part 1b. At the tip of the projection 1a, the gas flow path 1e connects to the reactive gas discharge hole 1d that is formed on the side surface of projection 1a. An opening 1f is formed on the other end of gas flow path 1e which introduces the reactive gas supplied by the gas supply unit 12 into the gas flow path 1e.

The reactive gas discharge hole 1d is opened in a direction that causes the reactive gas to be discharged in a direction that is substantially parallel to the bottom surface 1g of the cathode base plate 1h. With a construction wherein a plurality of reactive gas discharge holes 1d is formed in each projection 1a, the gas flow path 1e branches and connects to each reactive gas discharge hole 1d.

FIGS. 9(a) and (b) show an arrangement of projections 1a. In this arrangement, the distance between the side surfaces of adjacent projections 1a is either S1, the shortest distance, or S2, the longest distance. In these figures, the diameter of projection 1a is identified as D.

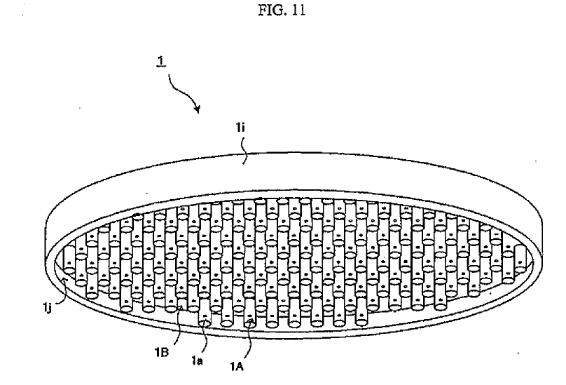

The concave section 1A which includes a plurality of projections 1a and the convex section 1B having the bottom surface 1g of the cathode base plate 1h are surrounded by outer wall 1i that is formed on the side wall portion of cathode base plate 1h. A hollow cathode discharge space is formed between the outside portion of concave section 1A and the wall face 1j of the outer wall 1i and projection 1a. FIG. 11 shows how the concave section and the convex section are surrounded by the outer wall 1i, the concave section 1A having a plurality of projections 1a and the convex section 1B formed by the bottom surface 1g of the cathode base plate 1h.

The diameter of the gas flow path 1e ranges between 0.5 mm and diameter D of the cathode column 1c. The diameter of the reactive gas discharge hole 1d is approximately between 0.1 mm and 1.0 mm. The plate thickness T of the cathode base plate 1h is approximately between 3 mm and 20 mm. The diameter D of the cathode column 1c ranges approximately between 2 mm and 6 mm. The protrusion length of projection 1a ranges approximately between 3 mm and 15 mm.

In one embodiment, T=5 mm and 7 mm, D=3 mm, S1=1.0 mm and 1.5 mm, H=5 mm and 7 mm, the diameter of the gas flow path is 1.0 mm, and the diameter of the reactive gas discharge hole is 0.4 mm. The reactive gas is assumed to be SiH₄, the pressure to be 70 Pa, and the ambient temperature to be 673K.

The distance S1 between the projections of the anode electrode can be estimated based on FIG. 4 through FIG. 6. For example, FIG. 6 shows that the mean free path MFP of SiH₄ at an ambient temperature of 673K and a pressure of 67 Pa is 1.06 mm and the mean free path MFP of NH to be 2.10 mm. With said embodiment, based on the value for the mean free path MFP of 1.06 mm that is obtained considering the main ingredient gas of SiH₄, S1 is set to be 1.0 mm or 1.5 mm.

The arrangement of the cathode column 1c that is arranged on the bottom surface 1g of the cathode base plate 1h is explained next.

The cathode distance is a major factor that determines the properties of a hollow cathode discharge. By using a multitude of cathode distances in the arrangement of the cathode electrodes, the optimum conditions for process parameters such as pressure, temperature and gas species can be broadly set. By arranging the cathode electrode in a close-packed array, a plurality of distances can be used between the respective electrodes, allowing the array of cathode electrodes to accommodate the case where the optimum electrode distance varies depending on the process conditions.

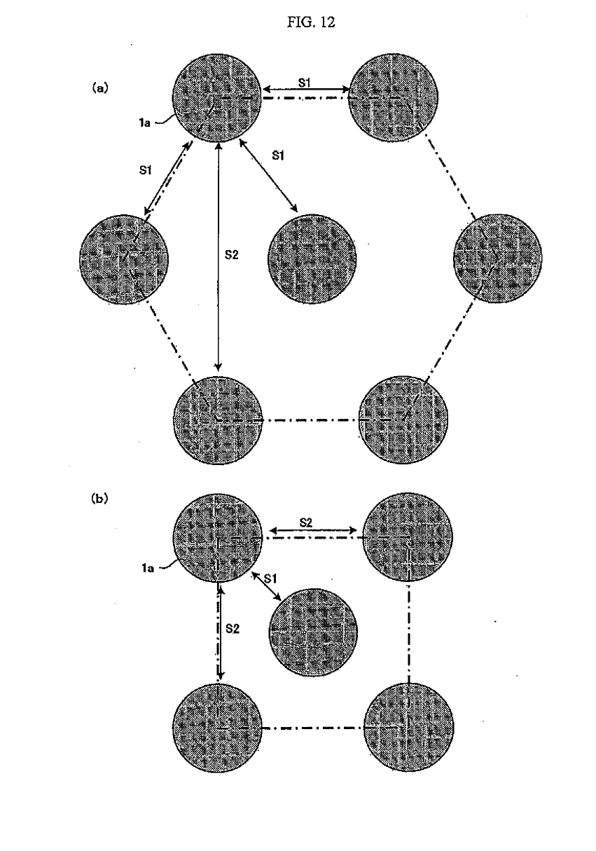

Examples of a hexagonal close-packed array and a square close-packed array are described next. A hexagonal close-packed array and a square close-packed array are explained with reference to FIG. 12.

In the hexagonal close-packed array shown in FIG. 12(a), the cathode electrode projections are positioned at the six vertices of the regular hexagon and at the center position surrounded by the six vertices. By positioning the cathode electrode projections (cathode columns) at these vertex positions and the central position, the distance between the side surfaces of adjacent projections 1a becomes a distance between the shortest distance S1 and the longest distance S2.

Also, with the square close-packed array shown in FIG. 12(b), the cathode electrode projections are positioned at the four vertices of a square and at a central position surrounded by the four vertices. By positioning the cathode electrode projections 1a (cathode columns 1c) at these vertex positions and the central position, the distance between the side surfaces of adjacent projections 1a becomes a distance between the shortest distance S1 and the longest distance S2.

In FIG. 12(a) and FIG. 12(b), the shortest distance S1 and the longest distance S2 are determined by the specific distances used for a particular arrangement and are not meant to suggest that the values are the same for every arrangement.

Furthermore, projections 1a (cathode columns 1c) that are provided need not all each have a reactive gas discharge hole 1d formed therein, and it is certainly acceptable for projections 1a (cathode columns 1c) with reactive gas discharge hole 1d formed therein and projections 1a (cathode columns 1c) without reactive gas discharge hole 1d to co-exist in a predetermined distribution pattern.

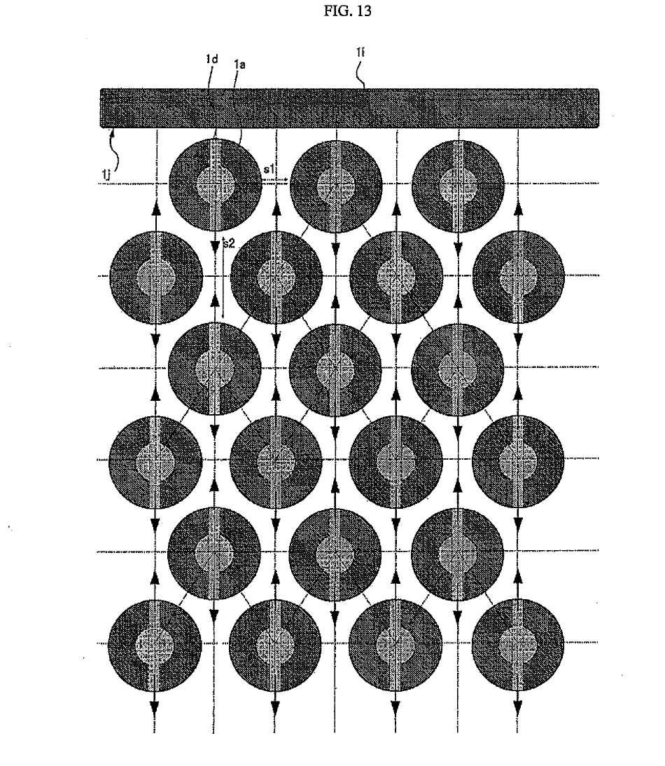

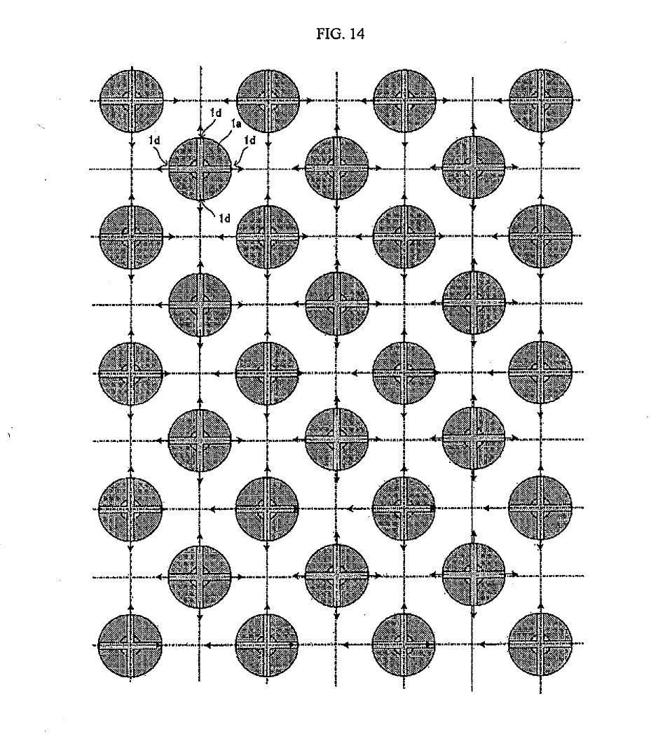

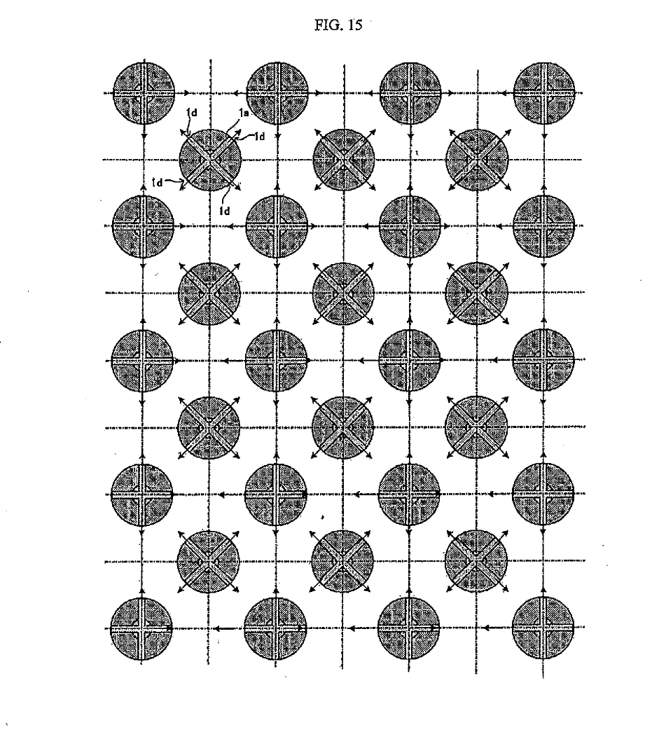

FIG. 13 through FIG. 15 show examples wherein all of the projections 1a (cathode columns 1c) each have a reactive gas discharge hole 1d formed therein. FIG. 13 shows an example of a hexagonal close-packed array. FIG. 14 and FIG. 15 show examples of a square close-packed array.

With the example shown in FIG. 13, projections 1a (cathode columns 1c) are arranged in a hexagonal close-packed array, and each projection 1a (cathode column 1c) has a reactive gas discharge hole 1d. The discharge direction is aligned with the direction of the longest distance S2 between adjacent projections 1a (cathode columns 1c).

With the example shown in FIG. 14, the projections 1a (cathode columns 1c) are arranged in a square array, and each projection 1a (cathode column 1c) has a reactive gas discharge hole 1d. The discharge direction is aligned with the direction of the longest distance S2 between adjacent projections 1a (cathode column 1c). Also, with the example shown in FIG. 15, the projections 1a (cathode columns 1c) are arranged in a square array, and each projection 1a (cathode column 1c) has a reactive gas discharge hole 1d. The discharge direction is a combination of a direction that is aligned with the direction of the longest distance S2 and the direction of the shortest distance S1 between adjacent projections 1a (cathode columns 1c).

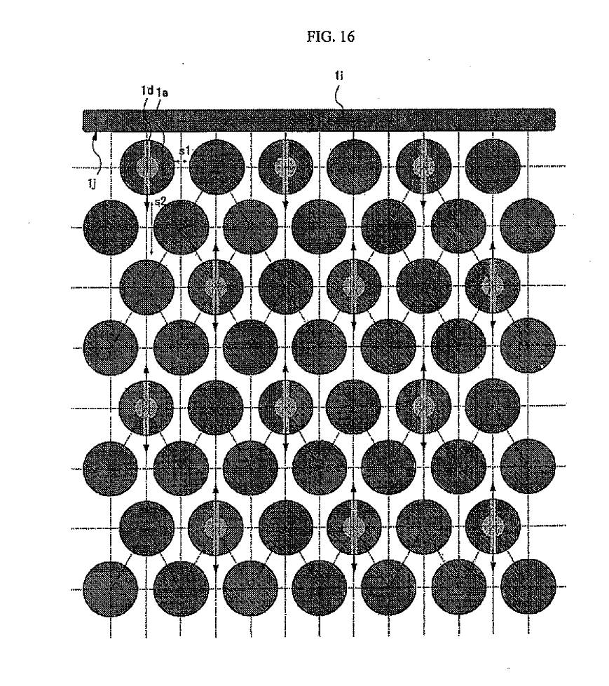

FIG. 16 shows an example wherein projections 1a (cathode columns 1c) with a reactive gas discharge hole 1d formed therein and projections 1a (cathode columns 1c) without a reactive gas discharge hole 1d co-exist in a predetermined distribution pattern. In this example, the ratio of the projections 1a (cathode columns 1c) with a reactive gas discharge hole 1d and projections 1a (cathode columns 1c) without a reactive gas discharge hole 1d is 1:3.

By providing projections 1a (cathode columns 1c) with a reactive gas discharge hole 1d and projections 1a (cathode columns 1c) without a reactive gas discharge hole 1d in a predetermined distribution pattern, the introduction of the reactive gas can be tailored to meet the process conditions determined by the gas species, pressure, temperature and the like.

The afore-described arrangement varies the distance between electrodes of adjacent projections 1a. At the same time, the reactive gas is uniformly discharged into the space between the electrodes.

Furthermore, with the examples shown in FIG. 13 through FIG. 16, the discharge direction of the reactive gas from the reactive gas discharge holes 1d lies on the same plane and is either in the same direction, is orthogonal to each other or is in a 45° direction. However, the discharge direction of the reactive gas may be in any direction for any one projection 1a (cathode column 1c), thus dispersing the discharge directions.

The shape of the cathode electrode projections 1a (cathode columns 1c) is not limited to a cylinder with a circular cross-sectional shape and may be elliptical instead. Furthermore, instead of a cylindrical column, it may be a polygonal column.

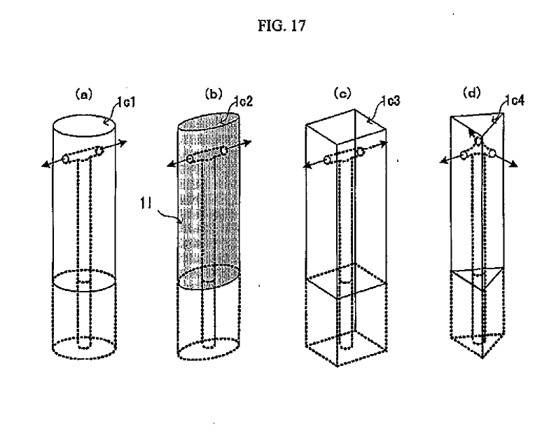

FIG. 17 shows examples of the shapes of the cathode electrode projection 1a (cathode column 1c).

FIG. 17(a) shows an example of a cylindrical structure with a circular cross-section. FIG. 17(b) shows an example of a cylindrical structure with an elliptical cross-section. FIG. 17(c) shows an example of a columnar structure with a rectangular cross-section. FIG. 17(d) shows an example of a columnar structure with a triangular cross-section. With the examples of the columnar structures shown in FIGS. 17(c) and (d), a reactive gas discharge hole may be formed in any or all of the column facets.

The modes of the present invention provide the following effects.

(a) In a hollow cathode discharge, by arranging the projections (cathode columns) of the concave section in a close-packed array and discharging the reactive gas in a direction parallel to the bottom surface of the convex section and the substrate, the area for the generation of a uniform, high density plasma is increased.

(b) By discharging the reactive gas in a direction parallel to the bottom surface of the convex section and the substrate, uneven gas density distribution of the reactive gas is reduced, thus suppressing the degradation of plasma uniformity and improving the uniformity of the thickness of the deposited film and the film quality.

(c) By using the configuration wherein the cathode columns that form the concave sections are inserted into openings that are formed in the bottom surface of the convex section, the manufacturing cost and time of the cathode electrode are reduced. Opening many fine holes in the cathode base plate to form concave-convex sections required for hollow cathode discharge entails much manufacturing cost and time and the manufacturing yield is poor. However, the construction where the projections (cathode columns) are inserted into the bottom surface eliminates the need for forming fine holes, shortens the manufacturing time and greatly improves the manufacturing yield.

(d) The configuration wherein the cathode columns that form the concave sections are inserted into openings that are formed in the bottom surface of the convex section allows replacement of the cathode columns, improving maintenance ease.

(e) The configuration wherein the cathode columns that form the concave sections are inserted into openings that are formed in the bottom surface of the convex section allows replacement of cathode columns with cathode columns of an optimum shape for the process conditions.

(f) Making the high density plasma uniform improves the film deposition rate.

(g) Arranging a plurality of cathode columns in a hexagonal close-packed array or a square close-packed array allows varying the distance between cathode electrodes. This broadens the range of optimum process conditions such as the range of optimum process pressure or optimum process temperature.

(h) With previous constructions of parallel plate electrodes, performing a high density, large area capacity-coupled radio frequency discharge required switching from, for example, a 13.56 MHz RF band frequency to a VHF band frequency to improve plasma density or to solve the problem of non-uniformity of the plasma density caused by standing waves. However, with the present invention, a large area, uniform high density plasma can be generated regardless of the power supply frequency.

(i) With the hollow cathode electrode, by introducing a gas into the convex section to be parallel to the bottom surface of the convex section and the substrate, the gas density is made uniform. This means that for the same process pressure, even if the gas flow rate is reduced by using a low expelling rate or by introducing the gas using a low flow rate, a stable and uniform high density plasma is generated.

### FIELD OF INDUSTRIAL USE

The use of the present invention is not limited to the manufacture of thin films for solar cells and can be used with sputtering apparatus, CVD apparatus, ashing apparatus, etching apparatus, MBE apparatus, vapor deposition apparatus and the like.

1. A cathode electrode for plasma CVD wherein a radio frequency is applied to form radio frequency capacity-coupled plasma, comprising:
the cathode electrode positioned to oppose an anode electrode; and
an opposing surface that opposes the anode electrode, having concave-convex sections comprising a convex section formed of a bottom surface and concave sections formed of a plurality of projections that protrude from the bottom surface of said convex section toward the anode electrode side,
wherein at least one of the projections of said concave sections has formed on its side surface at least one reactive gas discharge hole capable of discharging a reactive gas; and
the discharge direction of the reactive gas from said reactive gas discharge hole is approximately parallel to the bottom surface of the convex section.

2. The cathode electrode for plasma CVD according to claim 1, wherein each projection of the cathode electrode has formed therethrough a reactive gas flow path for supplying a reactive gas to the reactive gas discharge hole, said reactive gas flow path comprising a first flow path that runs in the axial direction of the projection and a second flow path that branches from said first flow path, connects to said reactive gas discharge hole and extends in a direction approximately parallel to the bottom surface.

3. The cathode electrode for plasma CVD according to claim 1, wherein the distance between adjacent projections of said cathode electrodes is in the range from 0.5 mm to 7 mm.

4. The cathode electrode for plasma CVD according to claim 1, wherein the hole diameter of the reactive gas discharge hole provided in the projection of said cathode electrode is in the range from 0.1 mm to 1.0 mm.

5. The cathode electrode for plasma CVD according to claim 1, wherein the height of the projection of said cathode electrode from the bottom surface is in the range from 3 mm to 15 mm.

6. The cathode electrode for plasma CVD according to claim 1, wherein the bottom portion of said cathode electrode and the side surface of the projection have fine concave-convex surface.

7. The cathode electrode for plasma CVD according to claim 1, wherein the projections of said cathode electrodes are disposed on the bottom surface of the convex section in a square close-packed array so that the projections are located at the four vertices of a square and at the center position surrounded by the four vertices.

8. The cathode electrode for plasma CVD according to claim 1, wherein the projections of said cathode electrodes are disposed on the bottom surface of the convex section in a regular hexagonal close-packed array so that the projections are located at the six vertices of a regular hexagon and at the center position surrounded by the six vertices.

9. The cathode electrode for plasma CVD according to claim 1, wherein the projections of said cathode electrodes with said reactive gas discharge hole formed therein and the projections without said reactive gas discharge hole formed therein are disposed on the bottom surface of the convex section with a predetermined distribution.

10. The cathode electrode for plasma CVD according to claim 9, wherein the ratio of the projections of said cathode electrode with said reactive gas discharge hole formed therein and the projections without said reactive gas discharge hole formed therein is 1:4, the projections of said cathode electrodes being formed on the bottom surface of the convex section at the six vertices of a regular hexagon and at the center position surrounded by the six vertices in a hexagonal close-packed array.

11. The cathode electrode for plasma CVD according to claim 1, wherein the projections of said cathode electrodes have a cylindrical shape with a circular horizontal cross-section.

12. The cathode electrode for plasma CVD according to claim 1, wherein the projections of said cathode electrodes have a polygonal columnar shape.

13. The cathode electrode for plasma CVD according to claim 1, wherein the projections of said cathode electrode have at least one said reactive gas discharge hole.

14. The cathode electrode for plasma CVD according to claim 1, wherein said cathode electrode comprises an outer peripheral wall that surrounds within it said projections, the height of the wall face of said outer peripheral wall being substantially the same as the height of the projections.

15. The cathode electrode for plasma CVD according to claim 1, wherein said cathode electrode is formed by inserting columns that constitute the projections into openings that are formed in a cathode base plate that constitutes the bottom surface.

16. A plasma CVD apparatus wherein a radio frequency is applied to form a radio frequency capacity-coupled plasma, comprising:
a vacuum chamber comprising a cathode electrode and an anode electrode;
a reactive gas supply unit that supplies a reactive gas to the upstream side of said cathode electrode in said vacuum chamber;
an exhaust unit that expels the reactive gas from within said vacuum chamber to outside the process chamber;
a controller that controls the pressure inside said vacuum chamber to a predetermined pressure;
an electrical power supply unit that supplies electrical power across said cathode electrode and said anode electrode; and
a substrate holder that positions a substrate to be processed between said cathode electrode and said anode electrode,
wherein said cathode electrode is a cathode electrode as described in claim 1; and
the reactive gas that is supplied by said reactive gas supply unit to the upstream side of the cathode electrode is discharged into the space between the cathode electrode and the anode electrode from the reactive gas discharge hole provided in the cathode electrode.

17. A solar cell that includes a thin film of any of a silicon semiconductor thin film, silicon nitride thin film, silicon oxide thin film, silicon oxynitride thin film and carbon thin film that is deposited using the plasma CVD apparatus according to claim 16.
